(19) United States
(12) Patent Application Publication
(10) Pub. No.: US 2005/0206016 A1
(43) Pub. Date: Sep. 22, 2005

(54) Semiconductor device and manufacturing method thereof, and liquid crystal module and semiconductor module having the same

(76) Inventors: Yasushi Shohji, Hiroshima (JP); Kenji Toyosawa, Hiroshima (JP)

Correspondence Address: HARNESS, DICKEY & PIERCE, P.L.C., P.O. BOX 8910, RESTON, VA, 20195, US

(21) Appl. No.: 11/082,756

(22) Filed: Mar. 18, 2005

(30) Foreign Application Priority Data
Mar. 22, 2004 (JP) 2004-083656
Mar. 17, 2005 (JP) 2005-077974

(51) Int. Cl. H01L 23/48

(52) U.S. Cl. 257/787

(57) ABSTRACT

Resin-sealing of a semiconductor element is carried out in two processes, by (I) forming a first sealing-resin layer by (i) sealing a connecting region of the semiconductor element and a wiring pattern with a first sealing resin, and (ii) curing the first sealing-resin, and then (II) forming a second sealing-resin layer by (i) providing the semiconductor element with a second sealing resin so that at least an edge portion of the semiconductor element is sealed, and (ii) curing the second sealing-resin. A semiconductor device thus obtained has a two-layer structure of the sealing-resin including (I) the first sealing-resin layer sealing the connecting region of the semiconductor element and the wiring pattern and (II) the second sealing-resin layer being so provided to the semiconductor element that at least an exposed edge portion of the semiconductor element is sealed.

This Nonprovisional application claims priority under 35 U.S.C. § 119(a) on Patent Application No. 2004/83656 filed in Japan on Mar. 22, 2004, and No. 2005/77974 filed in Japan on Mar. 17, 2005, the entire contents of which are hereby incorporated by reference.

### FIELD OF THE INVENTION

The present invention relates to a semiconductor device including (i) a film substrate on which a wiring pattern is provided, (ii) a semiconductor element including on its active surface a connection terminal to which the film substrate is connected, the semiconductor element being mounted so as to face the wiring pattern, the semiconductor device whose semiconductor element is sealed by sealing resin. The present invention also relates to a method for manufacturing the semiconductor device, and a liquid crystal module and a semiconductor module, each module having the semiconductor device.

### BACKGROUND OF THE INVENTION

Recently, demands for reduction of a size and thickness in, for example, a semiconductor module, for use in a mobile phone, a thin-model display or the like, is causing demand for reduction of a size and thickness in a semiconductor device being mounted in the semiconductor module, as well as demand for further improvement in packaging density and packaging reliability.

Under such circumstances, attentions are drawn to TCP (Tape Carrier Package) and COF (Chip On Film) as technologies for packaging an semiconductor element for use in the mobile phones and the thin-model displays (refer to, for example, Japanese Unexamined Patent Publications No. 64-81239/1989 (Tokukaishou 64-81239; published on Marc. 27, 1989)(Patent document 1), No. 1-196151/1989 (Tokukaihei 1-196151; published on Aug. 7, 1989)(Patent document 2), and No. 6-181236/1994 (Tokukaihei 6-181236; published on Jun. 28, 1994)(Patent document 3)). The TCP and COF both allows the semiconductor element to be flatly mounted on a mounting board of the semiconductor module.

These mounting methods are mounting methods for connecting the semiconductor element with electronic devices, such as liquid crystal display panel, of various semiconductor modules being provided in various modules such as a mobile phone and a liquid crystal display device, by (I) electrically connecting a bump electrode formed on a bonding pad of the semiconductor element with a terminal of a wiring pattern formed on the film substrate (base film) called a tape carrier, and (II) mounting the semiconductor element face-down on the tape carrier; i.e., with an active surface facing downward, and (III) connecting another terminal of the wiring pattern with the mounting board by soldering or the like.

The TCP has a structure having a projected wiring pattern called flying lead provided in a hole called device hole. This device hole is located in a position where the semiconductor element is mounted. To this flying lead, metal electrodes formed on the semiconductor element are connected.

It is required that the semiconductor element, for use in driving the liquid crystal display device, be made smaller and that the semiconductor element be capable of handling a large output. This requires a narrower wiring pitch at a connecting portion of the tape carrier. Typically, a wiring pattern is formed by processing a copper film of about 10 μm in thickness under a wet-etching. Narrower the wiring pitch becomes, less a strength of the flying lead in the TCP becomes. This causes a problem such as bending of lead wire. It is said that the wiring pitch of 40 μm is a minimum for acquiring a general performance.

On the other hand, the COF does not have the device hole. The wiring pattern for being connected to the metal electrodes formed on the semiconductor element is fixed on the tape carrier. This prevents the wiring pattern from being easily bent after the formation of the wiring pattern. Therefore, it is possible to realize a narrower wiring pitch than that of the TCP.

In the TCP or the COF, there are roughly two methods for bonding an external terminal of the semiconductor element with the tape carrier having the wiring pattern.

One of the methods is such that: resin called an under-filling (Hereinafter referred to as under-filling 5) for reinforcement of connecting portion and for an insulation (See FIG. 5) is filled in. After connecting the wiring pattern 3 formed on the tape carrier 4 and the metal electrodes 2 of the semiconductor 1 with each other, the under-filling 5 is filled in between (a) the semiconductor element 1 and (b) the tape carrier 4 and the wiring pattern 3.

Another method is such that: after connecting the wiring pattern 3 formed on the tape carrier 4 and the metal electrodes 2 of the semiconductor 1 with each other, the semiconductor element 1 is entirely sealed at once by molding or potting with resin 9 (See FIG. 6). For example, each of Patent documents 1 and 2 adopts this method shown in FIG. 6.

It should be noted that the potting is a process of applying, to a rear face of the semiconductor element 1, resin in liquid form by using a nozzle for supplying the resin, and then solidifying the resin being applied. Further, in general, resin-sealing by molding is carried out through a transfer molding (injection molding).

However, in the semiconductor device shown in FIG. 5, the strength of the semiconductor element 1 is insufficient due to the exposed rear face of the semiconductor element 1. This causes a damage in the step of mounting the semiconductor element 1 to the tape carrier 4, or in successive processes, which consequently lead to a problem such as chipping or cracking in the semiconductor element 1.

Further, in a semiconductor device shown in FIG. 6, resin is applied to the entire semiconductor element 1 from the rear face (i.e. from the top) of the semiconductor 1, so as to seal the entire semiconductor element 1. This causes various problems such as the following. Namely, the semiconductor element 1 may be tilted when being bonded. This causes positional deviation between the semiconductor element 1 and the wiring pattern 3, which results in poor packaging reliability. Further, the resin 9 is not sufficiently applied to a surface (i.e., bottom face) of the semiconductor element 1, so that a gap and/or a void occurs in the resin between the semiconductor element 1 and the tape carrier 4. As a result, the strength of the semiconductor element 1 is deteriorated. Further, a shrinkage of the resin 9 as to being cured causes the tape carrier to be warped (deformed).

As mentioned above, the TCP and COF both allow the semiconductor element 1 to be flatly mounted on the mounting board of the semiconductor module. However, the strength of the semiconductor element 1 is inevitably deteriorated due to the reduction of the size and thickness of the semiconductor device, unless an improvement is made in a material, or a new material is introduced.

Further, in the case of the semiconductor device shown in FIG. 6 where the semiconductor element 1 is entirely sealed, through the potting, from the rear face of the semiconductor element 1, the entire semiconductor element 1 as well as the connecting portion thereof are completely sealed by the resin 9, so that a sealing region is likely to be larger. Further, in the case of sealing the entire semiconductor element 1 through molding, the sealing region is more remarkably enlarged.

Under such circumstances, there is a demand for (I) a small-size semiconductor device whose semiconductor element 1 is protected against an external force, the semiconductor device having a high packaging reliability and a high strength, and (II) a method for manufacturing the semiconductor device.

Further, the size and the thickness of the semiconductor element 1 tend to be reduced in recent years. This is because the size and the thickness of the packaging of the semiconductor element 1 is reduced.

The reduction of the size and the thickness of the semiconductor element 1 formed with a silicon wafer causes a deterioration in a thermal capacity thereof.

When a voltage is applied to the semiconductor element 1, the semiconductor element 1 generates a heat. A rate of generating the heat is higher under a low thermal capacity. A high temperature in the semiconductor element 1 may cause, for example, a change in a property of the semiconductor element 1, and a problem in a performance of the device, thus resulting in a lower reliability.

Therefore, in order to restrain the change in the property, in the case where the thickness of the semiconductor element 1 is reduced, it is necessary to efficiently disperse the heat generated in the semiconductor element 1.

### SUMMARY OF THE INVENTION

An object of the present invention is to (I) provide a small-size semiconductor device with a higher strength and a higher packaging reliability than those of a conventional semiconductor device, whose semiconductor element is protected against an external force, (II) provide a method for manufacturing the semiconductor device, and (III) a liquid crystal module and a semiconductor module, each module having the semiconductor device.

It is an additional object of the present invention to provide (I) the semiconductor device in which heat generated in the semiconductor element is efficiently dispersed, thereby restraining a change in a property of the semiconductor element, (II) the method for manufacturing the semiconductor device, and (III) the liquid crystal module and the semiconductor module, each module having the semiconductor device.

In order to achieve the former object, a semiconductor device of the present invention includes (A) a film substrate on which a wiring pattern is provided; and (B) a semiconductor element having, on its active surface, a connection terminal to be connected with the wiring pattern, the semiconductor element being mounted on the film substrate so that the connection terminal and the wiring pattern face each other, wherein: (I) the semiconductor element is provided with sealing resin, and (II) the sealing resin has a two-layer structure including (a) a first -resin sealing layer for sealing a connection region of the semiconductor element and the wiring pattern and (b) a second resin sealing layer being provided to the semiconductor element that at least an exposed edge portion of the semiconductor element is sealed.

Further, in order to achieve the former object, a method of the present invention for manufacturing a semiconductor device having (a) a film substrate on which a wiring pattern is provided; and (b) a semiconductor element having, on its active surface, a connection terminal to be connected with the wiring pattern, the semiconductor element being mounted on the film substrate, so that the connection terminal and the wiring pattern face each other, the semiconductor element being sealed by sealing resin, the method characterized by comprising the step of sealing the semiconductor element, the step being carried out in two processes of: (I) forming a first resin sealing layer by (i) a connection region of the semiconductor element and the wiring pattern with a first sealing resin, and (ii) curing the first sealing resin, and (II) forming a second resin sealing layer by (i) providing, to the semiconductor element, a second sealing resin so that at least an edge portion of the semiconductor element is sealed, and (ii) curing the second sealing resin, the second resin sealing layer being formed after forming the first resin sealing layer.

In the foregoing configuration, the sealing resin has a two-layer structure including the first resin sealing layer and the second resin sealing layer. That is to say that, by forming the first sealing-resin layer and the second resin sealing layer are formed in two processes, it is possible to form each of the layers through processes respectively being specialized for each of the sealing positions. Therefore, it is possible to provide a semiconductor device whose properties respectively meet the requirements.

That is, the connecting region of the semiconductor element and the wiring pattern are resin-sealed in advance. This restrains the semiconductor element from tilting, in the step of bonding, thus preventing positional deviation between the connection terminal and the wiring pattern. Therefore, it is possible to provide a semiconductor device with a high packaging reliability. Further, the connecting region of the semiconductor element and the wiring pattern can be sealed in a process specialized only for sealing the connecting region. This effectively reduces defects such as formation of air bubbles in the resin.

Further, with the foregoing configurations, the second sealing resin (second resin sealing layer) is provided to the semiconductor element so as to seal at least the edge portions of the semiconductor element where chipping easily takes place. This prevents the semiconductor element from being damaged due to an external force causing chipping and/or cracking of the semiconductor element.

Further with the foregoing configurations, it is possible to narrow the sealing regions sealed with the sealing resin, by carrying out the resin-sealing in two processes.

Therefore, it is possible to provide (A) a small-size semiconductor device whose semiconductor element is protected from an external force, the semiconductor device having a high strength and a high packaging reliability, and (B) a method for manufacturing such a semiconductor device. Further, since it is possible to narrow the sealing region sealed with the sealing resin, the foregoing configurations are advantageous in, for example, expanding a bendable region of a COF as to mounting it.

Further, a thickness of the semiconductor element varies depending on models, manufacturer, user specifications, or the like. However, by carrying out the resin-sealing in two processes as described above, it is possible to expand a range of adoptable thickness of the semiconductor element.

Further, in each of the foregoing configurations, the resin-sealing is carried out in two processes; that is, the sealing resin includes two layers. This allows the first resin sealing layer and the second resin sealing layer to be selectively used. As a result, it is possible to select resin respectively having properties required. As described, by adopting resin respectively specialized for the first and the second sealing resins, and by carrying out the respective sealings through specialized processes, it is possible to provide a semiconductor device whose properties respectively meet requirements.

Further, as mentioned above, the sealing resin has a two-layer structure of the first resin sealing layer and the second resin sealing layer, each of the layers respectively being made of sealing resin to which the functions required in a sealing resin layer are allotted. This allows development and selection of resin for specific purpose of use. As a result, it is possible to selectively use the resin, corresponding to the sealing position, with an improved property.

In the present invention, in order to achieve the additional object, it is preferable that the second resin sealing layer is made of resin having a higher heat conductivity than that of the semiconductor element.

By forming the second resin sealing layer with resin having a higher heat conductivity than that of the semiconductor element, it is possible to more efficiently disperse the heat generated in the semiconductor element. Thus, even in a case where a thin-type semiconductor element is adopted, the foregoing configuration restrains a change in the property caused by increase in the temperature of the semiconductor element, thereby preventing problems in operations of a device due to the change in the property. As a result, with the foregoing configuration, it is possible to protect the semiconductor element and to restrain a change in the property thereof caused by increase in the temperature, so that it is possible to provide a thin-type semiconductor device with a high mounting reliability.

Further, in order to achieve the additional object, it is preferable that the semiconductor device further include a heat dispersing plate, laminated on a surface opposite to the active surface of the semiconductor element, which is made of a material whose heat conductivity is higher than that of the semiconductor element.

Such a semiconductor device is achieved by carrying out the step of laminating a heat dispersing plate made of a material having a higher heat conductivity than that of the semiconductor element on a surface opposite to the active surface of the semiconductor element, after forming the first resin sealing layer and before forming the second resin sealing layer.

Further, the foregoing semiconductor device is obtained by carrying out the steps of (I) laminating a heat dispersing plate made of a material having a higher heat conductivity than that of the semiconductor element on a surface opposite to the active surface of the semiconductor element; (II) mounting the semiconductor element, on which the heat dispersing plate is laminated, on the film substrate; (III) forming the first resin sealing layer; and then (IV) forming the second resin sealing layer.

In the foregoing configuration, the semiconductor element has, on its surface opposite to the active surface, the heat dispersing plate made of the material whose heat conductivity is higher than that of the semiconductor element. This reinforces the semiconductor element, and restrains the temperature of the semiconductor element from increasing, by absorbing and dispersing the heat generated in the semiconductor element when a voltage is applied. As a result, it is possible to restrain a change in the property caused by increase in the temperature, and to avoid a risk of problems in operations caused by operating under a high temperature. Further, in order to achieve the former object, a semiconductor module of the present invention includes the semiconductor device of the present invention.

Further, in order to achieve the former object, a liquid crystal module of the present invention includes a semiconductor device having (I) an external connection terminal being connected with a liquid crystal panel; and (II) another external connection terminal connected with a printed wiring board.

Thus, in the foregoing configuration, the semiconductor module (e.g. the liquid crystal module) has the semiconductor device of the present invention. Therefore, it is possible to provide a liquid crystal module and a semiconductor module, each of which (A) being capable of protecting the semiconductor element from an external force, (B) having a semiconductor device whose size is reduced, the semiconductor device having a higher strength and a higher packaging reliability than those of a conventional semiconductor device, and (C) being capable of ensuring a sufficient bendable region, even when the film substrate is bent at the time of installation.

Further, in the present invention, since the semiconductor module (e.g. the liquid crystal module) has the semiconductor device of the present invention, the heat generated in a semiconductor element is efficiently dispersed. This restrains a change in a property of the semiconductor element caused by increase in temperature.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a cross sectional view of an embodiment of a semiconductor device in accordance with the present invention, and is showing a schematic configuration of a relevant portion of the semiconductor device.

FIGS. 2(a) and 2(b) are cross sectional views of another embodiment of a method in accordance with the present invention, for manufacturing the semiconductor element, and is showing a relevant portion of the semiconductor device.

FIGS. 3(a) to 3(c) are cross sectional views of yet another embodiment of a method in accordance with the present invention, for manufacturing the semiconductor element, and is showing a relevant portion of the semiconductor device.

FIG. 4 is a cross sectional view of still another embodiment of a semiconductor device in accordance with the present invention, and is showing a schematic configuration of a relevant portion of the semiconductor device.

FIG. 5 is a cross sectional view showing a schematic configuration of a relevant portion of a conventional semiconductor device.

FIG. 6 is a cross sectional view showing a schematic configuration of a relevant portion of another conventional semiconductor device

FIG. 7(a) is a cross sectional view schematically showing a configuration of the liquid crystal module of an embodiment in accordance with the present invention.

FIG. 7(b) is a cross sectional view schematically showing an alternative configuration of the liquid crystal module of an embodiment in accordance with the present invention.

### DESCRIPTION OF THE EMBODIMENTS

[Embodiment 1]

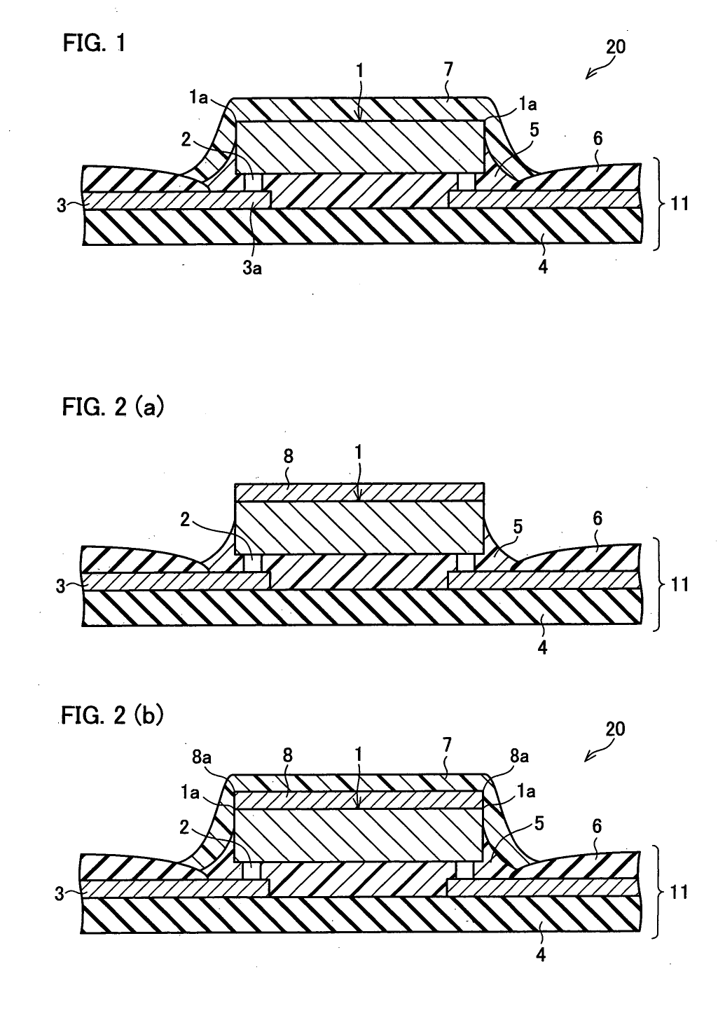

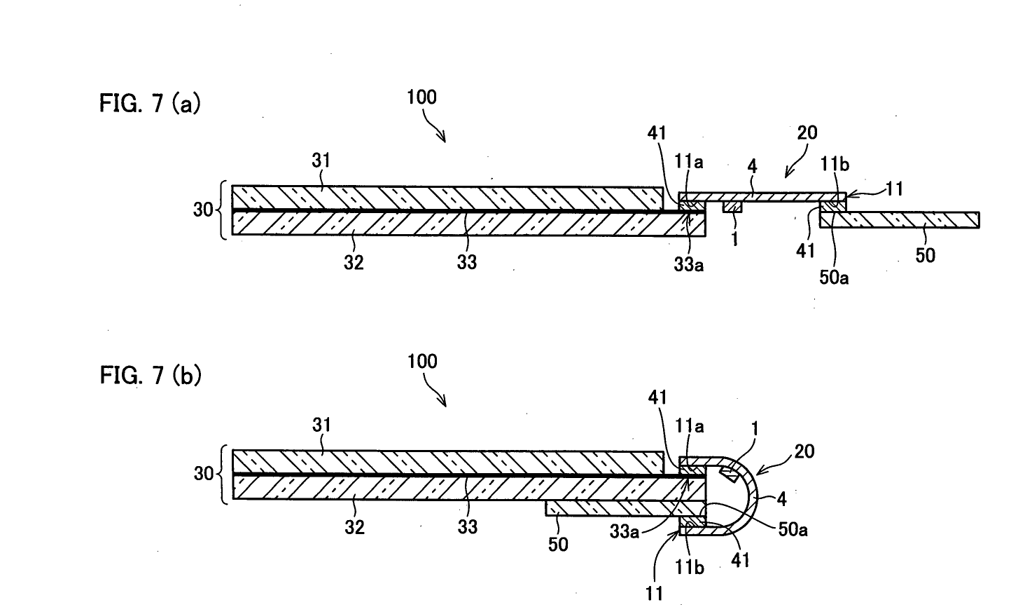

The following describes an embodiment of the present embodiment with reference to FIGS. 1, 7(a), and 7 (b).

FIG. 1 is a cross sectional view showing a schematic configuration of a semiconductor element mounting region in a semiconductor device of the present embodiment.

As shown in FIG. 1, the semiconductor device 20 of the present embodiment includes a wiring substrate 11 and a semiconductor element 1. The semiconductor element 1 is mounted on the wiring substrate 11 by using an under-filling (first resin sealing layer) 5. In a meanwhile, a rear face of the semiconductor element 1 is entirely coated with top-coating (second resin sealing layer) 7.

The semiconductor element 1 is for controlling a driving operation in an electronic device to which the semiconductor device 20 is mounted. For example, the semiconductor element 1 is made of a silicon wafer (monocrystal-silicon substrate). On this semiconductor element 1, a plurality of electrodes 2 serving as input/output electrodes (connection terminals each of which allows connection with the wiring pattern 3 described later) are formed on the semiconductor element 1 via the bonding pad. The metal electrodes 2 are projected bump electrodes made of metal material (conductive material). For those metal electrodes 2, for example, gold (Au) is suitable.

On the other hand, as shown in FIG. 1, the wiring substrate 11 has such a configuration that the wiring pattern 3 is provided on a tape carrier 4 (film substrate). The semiconductor element 1 is mounted on the wiring substrate 11 by a COF method, with an active surface of the semiconductor element 1 facing downward (i.e. face down), so that the metal electrodes 2 and the wiring pattern are connected with each other.

The tape carrier 4 is a flexible film made of an insulative material; for example, plastic made of polyimide resin, polyester resin, or the like. The wiring pattern 3 is formed by, for example, carrying out a wet etching with respect to a copper film of 5 to 20 μm in thickness being adhered to (fixed on) the tape carrier 4.

Further, regions other than connection terminal sections (connection terminal) 3a in the wiring pattern 3 and the metal electrodes 2 are covered by solder resist (protection film) 6. The solder resist is an insulative resin coating film (insulative material) which is made of epoxy resin or the like. As described, in the semiconductor device, the wiring pattern 3 is protected against oxidation or the like by using the solder resist 6 for coating the regions other than the connection terminal sections 3a.

The connection terminal sections 3a in the metal electrodes 2 and the wiring pattern 3 are bonded with each other by using a conductive adhesive agent such as solder, Ag paste, or Cu paste, so that a conductive state is acquired in the connection terminal sections 3a.

In the semiconductor element 1, the under-filling 5 is formed in a connecting region of the metal electrodes 2 and the wiring pattern 3; i.e., in a mounting region of the semiconductor element 1 (Hereinafter simply referred to as semiconductor element mounting region). This under-filling 5 is for reinforcing the connecting region and for providing an insulation (particularly for insulating the adjacent metal electrodes 2 or the adjacent connection terminal sections 3a).

The under-filling 5 is filled in between the semiconductor element 1 and the wiring substrate 11; i.e., between (a) the semiconductor element 1 and (b) the tape carrier 4 and the wiring pattern 3. When the wiring substrate 11 and semiconductor element 1 are connected with each other by heating and applying thereto a pressure, the insulative resin (under-filling material) for use in forming the under-filling 5 is fluidised. The fluidised insulative resin flows out of the semiconductor element 1 through a gap between the wiring substrate 11 and the semiconductor element 1. The resin is then solidified, and forms a fillet section (fin-like section) in a spreading-manner around the semiconductor element 1.

Then, the top-coating 7, for protecting the semiconductor element 1 and compensating the property thereof, is so provided on the semiconductor element 1 mounted on the wiring substrate 11, so as to cover the semiconductor element 1 as well as the under-filling 5. Thus, the semiconductor element 1 is completely covered by the top-coating 7.

For example, the insulative resin (first and second sealing resin) for use in forming the under-filling 5 and the top-coating 7 may be (I) photo-curing resin such as ultraviolet curing resin, or (II) thermosetting resin having transparency, such as epoxy resin, silicone resin, phenoxy resin, acrylic resin, polyether sulfone resin (PES resin). Among these transparent resin is preferable.

The under-filling 5 and the top-coating 7 may be made of an identical material or different materials. It is, however, preferable that the material be used (selected) based on properties required in each of the sealing regions to be sealed by the under-filling 5 and the top-coating 7.

In this case, for example, with respect to resin (under-filling 5) to be filled in the connecting portion between the wiring pattern 3 formed on the tape carrier 4 and the metal electrodes 2 formed on the semiconductor element 1, it is preferable to reinforce the connecting portion and suppress occurrence of leak current and formation of air bubbles by using resin excellent in adhesiveness, flowability, insulative property, moisture resistance, heat resistance, and anti-migration property. Further, with respect to resin (the top-coating 7) for covering the semiconductor element 1, it is preferable to protect the semiconductor element 1 from an external force and suppress a change in the property caused by increase in the temperature by using resin excellent in shock resistance, an excellent heat conductivity, and an excellent heat dissipation.

Particularly in a case of adopting the small and thin semiconductor element 1, it is necessary to efficiently disperse the heat generated in the semiconductor element 1, in order to prevent a heat-caused change in the property. By using, for the top-coating 7, the resin whose heat conductivity is more efficient than that of the semiconductor element 1, the semiconductor element 1 is protected, and at the same time, change in the property of the semiconductor element 1 is restrained.

Further, it is possible to improve water resistance of the semiconductor element 1 by adopting water-proof resin, particularly the water-proof resin having an excellent water resistance, for the top-coating 7.

For example, epoxy resin can be suitably used for the under-filling 5. In a meanwhile, silicone resin can be suitably used for the top-coating 7.

Thicknesses of the under-filling 5 and the top-coating 7 being formed are generally several tens to several hundreds of micro meters. However, the thicknesses of the under-filling 5 and the top-coating 7 are not limited to this, provided that the thicknesses are suitably adjusted in consideration of the thickness of the semiconductor element 1 and the height of the metal electrode 2, so that the respective sealing regions are sealed by the under-filling 5 and the top-coating 7.

Next described in the following is a method for manufacturing the semiconductor device 20 of the present embodiment; i. e., a method for mounting the semiconductor element 1 onto the wiring substrate 11.

First, a positioning of the semiconductor element 1 with respect to the wiring substrate 11 is carried out. That is, the metal electrodes 2 are positioned so as to correspond to the connection terminal sections 3a of the corresponding wiring pattern 3. Then, for example, a thermal compression bonding is carried out by using a bonding tool, so as to connect (bond) the metal electrodes 2 and the connection terminal sections 3a of the wiring pattern 3 with each other.

Then, in the connecting region (semiconductor element mounting region) of the wiring pattern 3 formed on the tape carrier 4 and the metal electrodes 2 formed on the semiconductor element 1, the under-filling material (first sealing resin), which is made of a material such as epoxy resin or silicone resin, for use in forming the under-filling 5 is filled in, dried and solidified, thereby sealing the connecting region with the under-filling material.

Formation of the under-filling 5; i.e., the filling-in of the under-filling material in the connecting region is carried out by (i) using a dispenser or the like for filling the under-filling material in the gap between the semiconductor element 1 and the tape carrier 4, and (ii) solidifying the under-filling material. It should be noted that the under-filling material may be ultraviolet curable resin. In this case, ultraviolet ray is irradiated for curing the under-filling material.

In the present embodiment, after forming the under-filling 5 by drying and curing the under-filling material, a top-coating material (second sealing resin) for forming the top-coating 7 is deposited so as to cover the semiconductor element 1 and the under-filling 5, and then the top-coating material is dried and cured. Thus, the rear face of the semiconductor element 1 is entirely covered by the top-coating 7. The top-coating material is resin or resin composition whose composition (constituent) is identical to or different from the under-filling material (both of them are hereinafter referred to as resin).

The semiconductor element 1 can be resin-sealed with the top-coating material by, for example, carrying out lithography using a dispenser.

Then, the semiconductor device thus obtained is subjected to a process in which, for example, a portion where the semiconductor element 1 is mounted is punched out from a long sheet of the tape carrier 4, and is mounted on a mounting board for a liquid crystal display panel or the like, as an individual semiconductor device.

As mentioned above, in the present embodiment, the semiconductor element 1 is entirely covered by the top-coating 7. This protects the semiconductor element 1, particularly an edge thereof where chipping easily takes place, against an external force causing chipping or cracking in the semiconductor element 1.

Further, in the present embodiment, only the semiconductor element 1 is mounted and resin-sealed in advance. This restrains the semiconductor element 1 from tilting, in the step of bonding, thus preventing positional deviation between the metal electrodes 2 with the connection terminal section 3a. Therefore, it is possible to provide a semiconductor device with a high packaging reliability. Moreover, the connecting region of the semiconductor element 1 and the wiring pattern 3 can be sealed in a process specialized only for sealing the connecting region. This effectively reduces defects such as formation of air bubbles in the resin.

As mentioned above, in the present embodiment, the resin is deposited in 2 steps; that is, the under-filling 5 and the top-coating 7 are separately formed. This allows the resin for the under-filling 5 and the resin for the top-coating 7 to be selectively used; for example, it is possible to (i) adopt the resin, which is advantageous in reinforcing the connecting region, and has an excellent insulative property and the like, for filling in the connecting region of the metal electrodes 2 formed on the semiconductor element 1 and the wiring pattern 3 formed on the tape carrier 4, and (ii) adopt the resin, which is protective against an external force, and has a high heat dissipation property, for covering the semiconductor element 1. Thus, it is possible to select the resin based on the properties required.

Further, conventionally, the rear face of the semiconductor element 1 has not been resin-sealed, or the entire semiconductor element 1 is resin-sealed by molding or potting, but in a single step (in one process). However, as mentioned above, in the present embodiment, the connecting region of the semiconductor element 1 is sealed in advance, and after the sealing resin in the connecting region has been cured, the protection sealing is carried out on the rear face of the semiconductor element 1. Thus, for the under-filling 5 and the top-coating 7, it is possible to use different materials respectively specialized for each of the properties, and it is possible to carry out the sealing through processes specialized for the respective sealing positions. As a result, there is provided a semiconductor device 20 which satisfies each of the properties required.

Further, as mentioned above, the sealing resin has two-layer structure of the under-filling 5 and the top-coating 7, each of the layers respectively being made of sealing resin to which functions required in the sealing resin are allotted. This allows development and selection of resin whose purpose of use is narrowed down. As a result, it is possible to selectively use the resin with an improved property corresponding to the sealing positions.

FIGS. 7(a) and 7(b) are cross sectional views schematically illustrating a configuration of a semiconductor module 20 of the present embodiment. It should be noted that the present embodiment deals with a case where a semiconductor module is the liquid crystal module 100. However the present invention is not limited to this. For example, the semiconductor module may be a display module other than the liquid crystal module.

As shown in FIGS. 7(a) and 7(b), the liquid crystal module 100 of the present embodiment is provided with (I) an upper glass substrate 31 interposed between polarizing plates (not shown), and (II) a liquid crystal panel (liquid crystal display panel) 30 (display panel) which is a connection-subjected element made of lower glass substrate 32.

Between the upper glass substrate 31 and the lower glass substrate, a liquid crystal layer (not shown) is interposed with a panel electrode 33 (liquid crystal driving electrode). The lower glass substrate 32 is longer than the upper glass substrate. A panel electrode terminal 33 serving as an external connection terminal of the panel electrode 33a is extended, and exposed on the lower glass substrate 32.

The liquid crystal module 100 is provided with, for example, a COF-type semiconductor device serving as a liquid crystal driver for driving the liquid crystal panel 30. This semiconductor device 20 is connected with a panel electrode terminal 33a formed on the lower glass substrate 32 in the liquid crystal panel 30 at a pattern terminal 11a (external connection terminal) formed on one end of the wiring substrate 11 in the semiconductor device 20, by using, for example an anisotropic conductive adhesive 41. Further, the semiconductor device 20 is connected with an external connection terminal 50a on a printed wiring board (PWB) 50 for imputing signals to the semiconductor device 20 at a pattern terminal 11b (external connection terminal) formed on another end of the wiring substrate 11 in the semiconductor device 20, by using, for example an anisotropic conductive adhesive 41.

Further, for example, the liquid crystal module 100 of the present embodiment may be so arranged as shown in FIG. 7(a) that the COF-type semiconductor device 20 is flatly connected with a liquid crystal panel. However, in order to connect the semiconductor device 20 with the liquid crystal panel 30, the semiconductor device 20 whose semiconductor element 1 is mounted on a side of the wiring pattern 3 (See FIG. 1) formed on the tape carrier 4, the semiconductor device 20 is turned over so that the semiconductor element 1 faces downward. By using an anisotropic conductive adhesive 41 or the like, (I) the pattern terminal 11a (external connection terminal) formed on an end of the tape carrier 4, i.e., one end of the wiring substrate 11 in the semiconductor device 20, and (II) a connecting portion of the electrodes formed on the lower substrate 31 serving as a mounting board of the liquid crystal panel 30, i.e., the panel electrode terminal 3a are connected with each other. Further, as shown in FIG. 7(b), as to mounting the wiring substrate 11, the wiring substrate 11 is bent in a U-shape, with (I) the same side as the semiconductor element 1 being mounted; i.e., the wiring pattern 3 of the wiring substrate 11, being inside, and (II) the tape carrier 4 serving as a base substrate being outside.

As mentioned above, in the present embodiment, it is possible to narrow down the resin region, by carrying out the resin sealing in two processes. As a result, for example, it is possible to expand a bendable region which allows the tape carrier 4 to be bent as to mounting the semiconductor device 20.

Further, a thickness of the semiconductor element 1 varies depending on models, manufacturer, user specifications, or the like. However, by carrying out the resin-sealing in two processes as described above, it is possible to expand a range of adoptable thickness of the semiconductor element 1.

It should be noted that the present embodiment deals with a case where a lithography carried out by using a dispenser is adopted for carrying out the resin-sealing with the under-filling 5 and the top-coating 7. However, the present embodiment is not limited to such a case. For example, it is possible to (I) use a nozzle for applying (dropping) the under-filling material around the periphery of the semiconductor element 1, (II) cause the under-filling material to flow into the gap between the semiconductor element 1 and the tape carrier 4, and (III) curing the under-filling material by heating through re-flow heating or the like.

Further, a material of the top-coating 7 may be sheet-like thermoplastic resin or photo-curing resin. In this case, the semiconductor element 1 can be covered simply by depositing the sheet-like material for the top-coating 7 on the semiconductor element 1, and, for example, heating and applying a pressure to the material under a vacuum heating atmosphere.

[Embodiment 2]

An embodiment of the present invention is described with reference to FIGS. 2(a) and 2(b). It should be noted that the same symbols are given to the members that have the same functions as those shown in figures of the foregoing embodiment 1, and the descriptions of those members are omitted here as a matter of convenience. The present embodiment mainly deals with differences from the foregoing embodiment 1.

FIGS. 2(a) and 2(b) are cross sectional views illustrating a method for manufacturing a semiconductor device of the present embodiment. FIGS. 2(a) and 2(b) both show cross sectional views of a semiconductor element mounting region in the semiconductor device of the present embodiment.

As shown in FIGS. 2(a) and 2(b), the semiconductor device 20 of the present embodiment is arranged so that: on a top surface of a semiconductor element 1 (rear face; i.e., a surface opposite to an active surface serving as a functioning circuit) being fixed above a tape carrier 4 on which a wiring pattern 3 is provided, a metal plate 8 serving as a heat dispersing plate whose heat-conductivity is more efficient than that of the semiconductor element 1 is provided, and a top-coating 7 is provided on top of the metal plate 8 so as to cover the semiconductor element 1.

More specifically, the heat dispersing plate is made of, for example, a copper plate, an aluminium plate, or the like. However, the heat dispersing plate is not particularly limited, provided that the heat-conductivity thereof is more efficient than that of the semiconductor element 1.

With the present embodiment, since the metal plate 8 (heat dispersing plate) is laminated on the rear face of the semiconductor element 1, the semiconductor element 1 is further reinforced. Moreover, while the semiconductor device 20 is driven, heat generated by an application of voltage is absorbed and dispersed, thereby restraining a temperature of the semiconductor element 1 from increasing. As a result, it is possible to avoid a risk of malfunction caused by operating under a high temperature.

Accordingly, in the present embodiment, the metal plate 8 is arranged on the rear face of the semiconductor element 1, and further, the top-coating 7 is deposited on the metal plate 8, thereby completely covering the semiconductor element 1 and the metal plate 8 with the top-coating 7. This allows further reinforcement of the semiconductor element 1 and further enlargement of the heat capacitance. Further, since the heat generated in the semiconductor element 1 is more efficiently dispersed, it is possible to restrain a change in a property caused by the increase in temperature. Therefore, it is also possible to meet even prospective severe requirements in a performance. Further, in the present embodiment, the semiconductor element 1 and the metal plate 8 are protected against an external force. It is needless to say that, in the present embodiment as well, packaging reliability of the semiconductor 1 is improved, and defects such as air bubbles in resin are effectively reduced, as in the case with the foregoing embodiment 1, by selecting a specialized process and specialized resin.

Next, the following describes a method for manufacturing the semiconductor device 20 of the present embodiment; that is, a method for mounting the semiconductor element 1 onto the wiring substrate 11.

The method of the present embodiment is the same as that of the foregoing embodiment 1, up to the process in which the connection region (semiconductor mounting region) of the wiring pattern 3 formed on the tape carrier 4 and the metal electrodes 2 formed on the semiconductor element 1 are sealed with the under-filling 5.

In the present embodiment, after the under-filling material is filled, dried and cured in the connection region of (I) the metal electrodes 2 and (II) the wiring pattern formed on the tape carrier 4, the metal plate 8, which is copper plate or an aluminium plate, is fixed on the exposed rear face of the semiconductor element 1.

The metal plate 8 can be fixed by using, for example, conventionally known conductive adhesive agent such as soldering iron, Ag paste, or Cu paste. Therefore, it is possible to adhere (electrically connect) the metal plate 8 to the semiconductor element 1, without spoiling a conductive state.

Then, as shown in FIG. 2(b), the semiconductor element 1 is completely covered with the top-coating 7 by (I) depositing the top coating-material which is resin having a composition identical to or different from the under-filling 5 on the semiconductor element 1, so that the semiconductor element 1 as well as the metal plate 8 and the under-filling 5 are covered, and then (II) drying, and curing the top-coating 7.

It should be noted that, in a case of using a sheet-like top-coating material in the present embodiment, the metal plate 8 placed on the semiconductor element 1 may be covered with the sheet-like top-coating material 7. Further, it is not necessary to fix the metal plate 8 on the semiconductor element 1 in advance, provided that a position of the metal plate 8 is not affected by placing thereon the top-coating material.

Further, it is not necessary to form the metal plate 8 beforehand, in the form of a plate. For example, it is possible to form the metal plate (metal layer) 8 directly on the semiconductor element 1 by, for example, laminating, plating, or depositing a metal material on the semiconductor element 1.

Thickness of the metal plate (heat dispersing plate) 8 is generally several tens to several hundreds of micro meters. However, the thickness of the metal plate 8 is not limited to this, provided that the thickness is suitably adjusted based on required performance, such as heat conductivity, and material being used.

As in the foregoing embodiment 1, the semiconductor device thus obtained is subjected to a process in which, for example, a portion where the semiconductor element 1 is mounted is punched out from a long sheet of the tape carrier 4, and is mounted on a mounting board for a liquid crystal display panel or the like, as an individual semiconductor device 20.

[Embodiment 3]

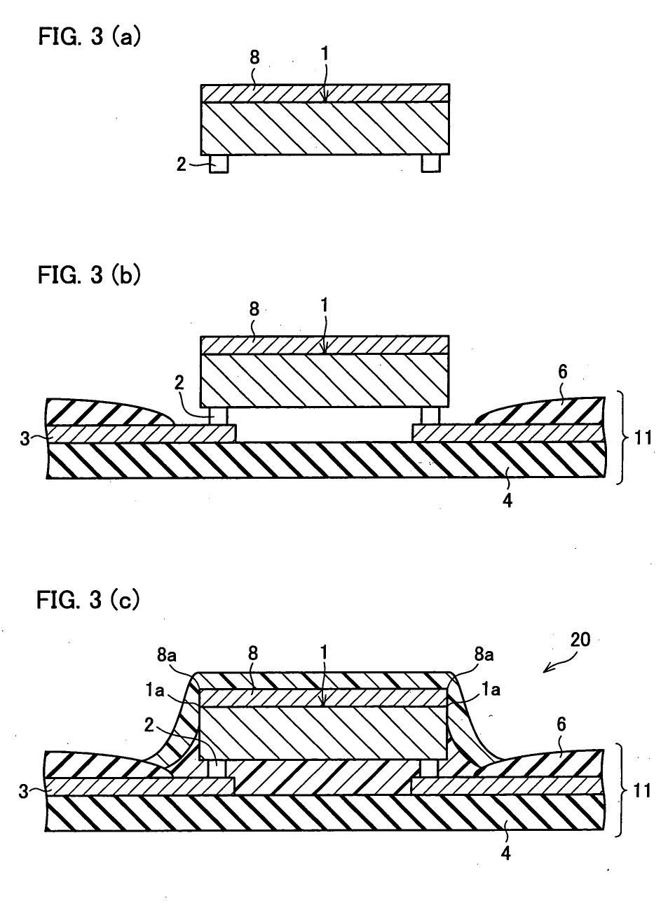

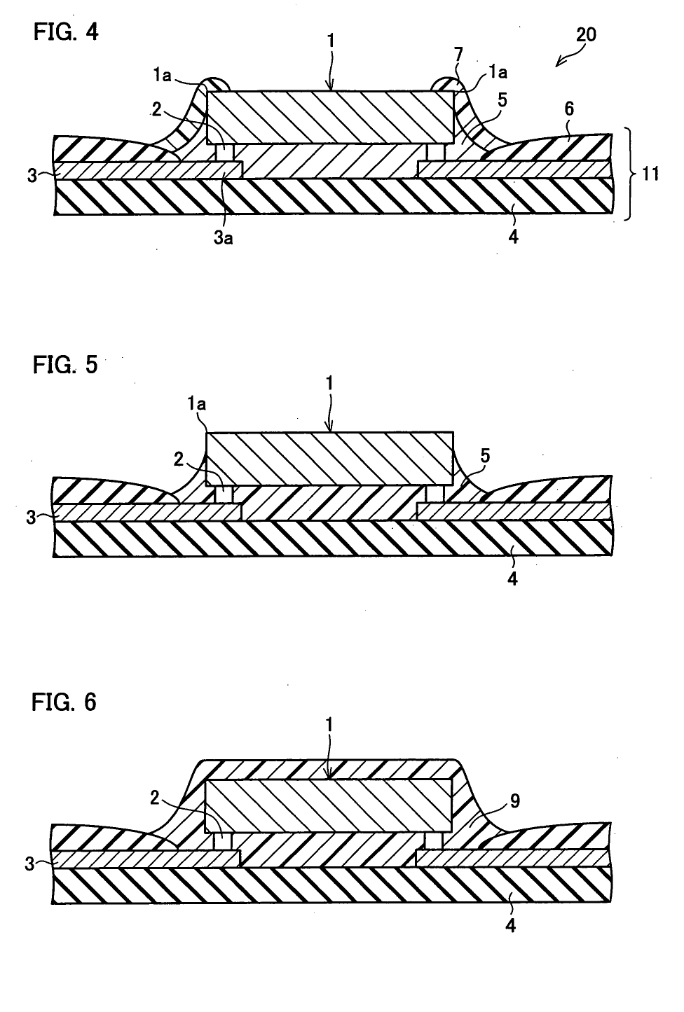

An embodiment of the present invention is described with reference to FIGS. 3(a) to 3(c) and 4. It should be noted that the same symbols are given to the members that have the same functions as those shown in figures of the foregoing embodiments 1 and 2, and the descriptions of those members are omitted here as a matter of convenience. The present embodiment mainly deals with differences from the foregoing embodiment 1.

FIGS. 3(a) to 3(c) are cross sectional views illustrating a method for manufacturing a semiconductor device of the present embodiment. FIGS. 3(a) and 3(c) both show cross sectional views of semiconductor element mounting region in the semiconductor device of the present embodiment.

As shown in FIG. 3(c), the semiconductor device 20 of the present embodiment has an identical configuration to the semiconductor device 20 of the foregoing embodiment 2. However, the manufacturing processes are different.

Next, the following describes a method for manufacturing the semiconductor device 20 of the present embodiment; that is, a method for mounting the semiconductor element 1 onto the wiring substrate 11.

In the foregoing embodiment 2, a semiconductor element 1 and a metal plate 8 are completely covered by a top-coating 7, by (I) fixing the metal plate (heat dispersing plate) 8 on an exposed rear face of the semiconductor element 1, so that the rear face of the semiconductor element 1 is protected, and a thermal capacity is increased, and (II) depositing and curing a top-coating material, after (a) mounting the semiconductor element 1 on a tape carrier 4, and (b) forming an under-filling 5 by filling an under-filling material in a connecting region of the tape carrier 4 and the semiconductor element 1, then drying and curing the under-filling material.

However, as shown in FIG. 3(a), in the present embodiment, a metal plate 8 whose heat conductivity is more efficient than that of the semiconductor element 1 is fixed on the semiconductor element 1. In the present embodiment as well, the metal plate 8 can be fixed on the semiconductor element 1 by, for example, using conductive adhesive agent such as soldering iron, Ag paste, Cu paste. The method of adhering (fixing) is not particularly limited, provided that the metal plate 8 is made to adhere (electrically connected) to the semiconductor element 1 in a conductive state.

More specifically, as shown in FIG. 3(b), in the present embodiment, positioning of the semiconductor element 1 with respect to the wiring substrate is carried out with the metal plate 8 being fixed on the rear face of the semiconductor element 1. The positioning of the semiconductor element 1 with respect to the wiring substrate 11 is as described in the foregoing embodiment 1. After the under-filling 5 is filled in a connecting region of metal electrodes 2 and a wiring pattern 3 formed on the tape carrier 4 as in the case of the embodiment 1, the semiconductor element 1 is completely covered by the top-coating 7 as in the case with the foregoing embodiment 2, by depositing, drying, and curing resin whose composition is identical to or different from the under-filling 5 on the semiconductor element 1, so as to cover the semiconductor element 1 as well as the metal plate 8 and the under-filling 5.

As in the foregoing embodiments 1 and 2, the semiconductor device 20 thus obtained is subjected to a process in which, for example, a portion where the semiconductor element 1 is mounted is punched out from a long sheet of the tape carrier 4, and is mounted on a mounting board for a liquid crystal display panel or the like, as an individual semiconductor device 20.

As mentioned above, in the present embodiment, the metal plate 8 (heat dispersing plate) is laminated, as in the case with the foregoing embodiment 2, on the rear face of the semiconductor element 1, thereby further reinforcing the semiconductor element 1. Further, while the semiconductor device 20 is driven, heat generated by an application of voltage is absorbed and dispersed. This restrains a temperature of the semiconductor element 1 from increasing. As a result, it is possible to avoid a risk of malfunction caused by operating under a high temperature. Thus, the same effects as the foregoing embodiment 2 are obtained.

Further in the present embodiment, the metal plate (heat dispersing plate) 8 is fixed on the semiconductor element 1, before the semiconductor element 1 is mounted on the tape carrier 4. This realizes a stable state of connection (bonding) between the tape carrier 4 and the semiconductor element 1.

Further, unlike a case where the metal plate 8 is laminated prior to the resin-sealing and after the semiconductor element 1 is mounted, it is possible to prevent discontinuation of line in the connecting (bonding) section between the tape carrier 4 and the semiconductor element 1 by laminating (fixing) the metal plate 8 before the semiconductor element 1 is mounted on the tape carrier 4. Further, unlike a case where the metal plate is laminated after the resin-sealing, it is possible to prevent the tape carrier 4 from bending after the resin-sealing, thereby preventing fluctuation in parallelism. This allows stable production of the semiconductor element 1.

It should be noted that the foregoing embodiments 1 through 3 deal with a configuration in which the semiconductor element 1 is completely covered with the top-coating 7; i.e., the rear face of the semiconductor element 1 or the rear face of the metal plate 8 is completely covered. However, the present invention is not limited to this, and in order to protect edge portions (verges) of the semiconductor element 1 where chipping can easily take place, for example, the top-coating 7 may cover only edge portions 1a of the semiconductor element 1, so as to cover at least the edge portions being exposed; that is, edge portions 1a of the semiconductor element 1 which are exposed at the time of the top-coating 7 formation (i.e., edge portions 1a on the rear face of the semiconductor element 1, and even edge portions 1a from the rear face to the side faces of the semiconductor element 1 (See FIG. 4). It should be further noted that FIG. 4 shows the configuration in which the top-coating 7 partially covers, from the top of the under-filling 5, the edge portions 1a of the semiconductor element 1. However, the configuration may be such that the top-coating 7 covers only the edge portions 1a on the top surface of the semiconductor element 1, more specifically, exposed edge portions (e.g. only the edge portions 1a on the top surface of the semiconductor element 1 not being covered by the under-filling 5). In this case, it is possible to narrow a resin-sealing region in the semiconductor device 20, and to provide a semiconductor device 20 whose size is further reduced.

It should be noted that, in the foregoing embodiments 2 and 3, the rear face of the semiconductor element 1 is arranged with the metal plate 8 serving as the heat dispersing plate whose size and shape is identical to the rear face of the semiconductor element 1. However, the present embodiment is not limited to this, and the heat dispersing plate may be a heat dispersing plate whose size is smaller or larger than that of the rear face of the semiconductor element 1.

In a case where the heat dispersing plate is smaller than the rear face of the semiconductor element 1, it is not necessary to cover the heat dispersing plate with the top-coating 7, provided that the heat dispersing plate is made of, for example, a material having an excellent shock resistance, such as silicone rubber, and the configuration may be such that the top-coating 7 only covers the edge portion 1a of the semiconductor element 1, where chipping easily take place (i.e., only the exposed edge portions 1a of the semiconductor element 1, not being covered by the under-filling 5 and the heat dispersing plate (metal plate 8)). For example, in a case where the heat dispersing plate is smaller than the rear face of the semiconductor element 1, the top-coating 7 may cover only the edge portions 1a from the rear face to the side faces of the semiconductor element 1. Further, in a case where the heat dispersing plate is larger than the rear face of the semiconductor element 1, the top-coating may cover only the edge portions 1a of the side faces of the semiconductor element 1.

However, in order to protect an edge portion 8a of the metal plate 8, and to improve connection strength, it is preferable that the top-coating 7 cover not only the edge portion 1a of the semiconductor element 1, but also the edge portion 8a (See FIGS. 2(b) and 3(c)) of the metal plate 8.

Further, in order to increase the thermal capacity of the semiconductor element 1, and to restrain a change in the property due to an increase in temperature, the top-coating 7 and/or the metal plate 8, each of which has higher heat conductivity than that of the semiconductor element 1, preferably cover most of the rear face of the semiconductor element 1, more preferably the entire rear face of the semiconductor element 1. Particularly, as described in the foregoing embodiment 1, in a case where the metal plate is not arranged on the rear face of the semiconductor element 1, it is preferable that the entire rear face of the semiconductor element 1 is covered with the top-coating 7, particularly with the top-coating 7 made of a material (resin) having higher heat conductivity than that of the semiconductor element 1. Thus, the heat generated in the semiconductor element 1 is more efficiently dispersed, and the change in the property of the semiconductor element, due to an increase in temperature, is restrained.

Further, the foregoing embodiments 1 through 3 deal with an example of an COF (Chip On Film) in which (I) the semiconductor element 1 is mounted, with an active surface thereof facing down, on the wiring substrate 11; i.e. on the tape carrier 4 (film substrate) having a wiring pattern 3, and (II) the metal electrode 2 provided on the active surface and the wiring pattern 3 are electrically connected with each other. However, the present embodiment is not limited to this, and the semiconductor device 20 may be a TCP (Tape Carrier Package), in which (I) a hole called a device hole is provided on the tape carrier 4, and (II) the semiconductor element 1 is mounted by using a wiring pattern called flying lead projecting within the device hole.

However, as mentioned above, since the present invention allows narrowing down of the resin-sealing region by carrying out the resin-sealing in two processes, it is preferable that the present invention be adopted to the COF, in consideration with a bendable region of the tape carrier 4.

As mentioned above, a semiconductor device of the present invention is arranged so that the sealing resin has a two-layer structure including (i) a first resin sealing layer for sealing a connection region of the semiconductor element and the wiring pattern and (ii) a second sealing resin layer being so provided to edge portions of the semiconductor element that at least an exposed (uncoated) edge portion of the semiconductor element is sealed.

Further, the semiconductor device of the present invention may be arranged so that the sealing resin has the two-layer structure including (i) the first resin sealing layer for sealing a connection region of the semiconductor element and the wiring pattern and (ii) the second sealing resin layer being so provided to the semiconductor element that at least the edge portions of the semiconductor element is sealed.

Further, as mentioned above, a method of the present invention for manufacturing a semiconductor device includes the step of sealing the semiconductor element, the step being carried out in two processes of: (I) forming a first resin sealing layer by (i) a connection region of the semiconductor element and the wiring pattern with a first sealing resin, and (ii) curing the first sealing resin, and (II) forming a second sealing resin layer by (i) providing, to edge portions of the semiconductor element, a second sealing resin so that at least an exposed (uncoated) edge portion of the semiconductor element (1) is sealed, and (ii) curing the second sealing resin, the second sealing resin layer (7) being formed after forming the first sealing resin layer (5).

Further, the method of the present invention for manufacturing a semiconductor device may include the step of sealing the semiconductor element, the step being carried out in two processes of: (I) forming the first resin sealing layer by (i) the connection region of the semiconductor element and the wiring pattern with the first sealing resin, and (ii) curing the first sealing resin, and (II) forming the second sealing resin layer by (i) providing, to the edge portions of the semiconductor element, the second sealing resin so that at least the edge portions of the semiconductor element is sealed, and (ii) curing the second sealing resin, the second sealing resin layer (7) being formed after forming the first sealing resin layer (5).

In the foregoing configuration, the sealing resin has a two-layer structure including the first resin sealing layer and the second resin sealing layer. In other words, the first sealing resin and the second resin sealing layer are formed in two processes. This restrains the semiconductor element from being tilted as to bonding, and prevents positional deviation between the connection terminal and the wiring pattern. Therefore, it is possible to provide a semiconductor device with a high packaging reliability. Further, with the foregoing configuration, the sealing of the connecting region of the semiconductor element and the wiring pattern is carried out under a process specialized for sealing the connection region. Therefore, it is possible to more effectively reduce defects such as formation of air bubbles in the resin.

Further, with the foregoing configurations, the second sealing resin seals the semiconductor element so as to cover at least an edge portion, particularly the edge portion being exposed, of the semiconductor element where chipping easily takes place. This prevents the semiconductor element from being damaged due to an external force causing chipping and/or cracking of the semiconductor element.

Thus, with the foregoing configurations, each of the resin sealing layers is formed through a process specialized for each sealing position. As a result, it is possible to provide a semiconductor device whose properties satisfies respective requirements.

Further, with the foregoing configurations, it is possible to narrow the sealing regions sealed with resin, by carrying out the resin sealing in two processes. Therefore, it is possible to (A) protect the semiconductor element from an external force, (B) provide a semiconductor device whose size is reduced, the semiconductor device having a high strength and a high packaging reliability, and (C) a method for manufacturing such a semiconductor device. Further, since it is possible to narrow the sealing region sealed with the sealing resin, the foregoing configurations are advantageous in, for example, expanding a bendable region of a COF as to mounting it.

Incidentally, a thickness of the semiconductor element differs depending on models, manufacturers, or user specifications and so on. However, by carrying out the resin-sealing in two processes as described, it is possible to expand an adoptable thickness range of the semiconductor element.

Further, in each of the foregoing configurations, the resin-sealing is carried out in two processes; that is, the sealing resin includes two layers. This allows the first sealing resin and the second sealing resin to be selectively used. As a result, it is possible to select resin respectively having properties required. As described, by (I) adopting resin respectively specialized for the first and the second sealing resins, and (II) carrying out the respective sealings through specialized processes, it is possible to provide a semiconductor device whose properties respectively meet requirements.

Further, with the foregoing configuration, it is possible to allocate each required function of the sealing resin to each layer. This allows the resin to be developed and selected for a specific purpose. As a result, it is possible to selectively use the resin having better property corresponding to the sealing position.

As mentioned above, according to the present invention, it is preferable that different types of resin be used for the first sealing resin and the second sealing resin. In other words, it is preferable that resin constituting the first resin sealing layer and resin constituting the second resin sealing layer are different from each other.

Further, it is preferable that the second resin sealing layer is made of resin having a higher heat conductivity than that of the semiconductor element.

By forming the second resin sealing layer with resin having a higher heat conductivity than that of the semiconductor element, it is possible to more efficiently disperse the heat generated in the semiconductor element. Thus, even in a case where a thin-type semiconductor element is adopted, the foregoing configuration restrains a change in the property caused by increase in the temperature of the semiconductor element, thereby preventing problems in operations of a device due to the change in the property. As a result, with the foregoing configuration, it is possible to protect the semiconductor element and to restrain a change in the property thereof caused by increase in the temperature, so that it is possible to provide a thin-type semiconductor device with higher reliability.

Further, it is preferable that the semiconductor device further include a heat dispersing plate, laminated on a surface opposite to the active surface of the semiconductor element, which is made of a material whose heat conductivity is higher than that of the semiconductor element.

Such a semiconductor device is achieved by carrying out the step of laminating a heat dispersing plate made of a material having a higher heat conductivity than that of the semiconductor element on a surface opposite to the active surface of the semiconductor element, after forming the first resin sealing layer and before forming the second resin sealing layer.

Further, the foregoing semiconductor device is obtained by carrying out the steps of (I) laminating a heat dispersing plate made of a material having a higher heat conductivity than that of the semiconductor element on a surface opposite to the active surface of the semiconductor element; (II) mounting the semiconductor element, on which the heat dispersing plate is laminated, on the film substrate; (III) forming the first resin sealing layer; and then (IV) forming the second resin sealing layer.

In the foregoing configuration, the semiconductor element has, on its surface opposite to the active surface, the heat dispersing plate made of the material whose heat conductivity is higher than that of the semiconductor element. This reinforces the semiconductor element, and restrains the temperature of the semiconductor element from increasing, by absorbing and dispersing the heat generated in the semiconductor element when a voltage is applied. As a result, it is possible to restrain a change in the property caused by increase in the temperature, and to avoid a risk of malfunction caused by operating under a high temperature.

Further, unlike a case of laminating the heat dispersing plate after the semiconductor element is mounted and before the resin-sealing is carried out, discontinuation in the connecting (bonding) section of the film substrate and the semiconductor element is more likely to be prevented by laminating (fixing) the heat dispersing plate before the semiconductor element is mounted on the film substrate. Further, unlike a case where the heat dispersing plate is laminated after the resin-sealing, it is possible to prevent fluctuation in parallelism caused by warpage of the film substrate after the resin-sealing and to more stably manufacture the semiconductor element.

Further, in the present invention, the second resin sealing layer is preferably formed so as to cover the semiconductor element as well as the heat dispersing plate.

By forming the second resin sealing layer so as to cover the semiconductor element as well as the heat dispersing plate, it is possible to further reinforce the semiconductor element, and to further increase the thermal capacity of the semiconductor element. Further, since the heat generated in the semiconductor element is more efficiently dispersed, it is possible to further restrain a change in the property caused by increase in the temperature.

As mentioned above, with the method of the present invention for manufacturing a semiconductor device, it is possible to provide a small-size semiconductor device with a high strength and a high packaging reliability, whose semiconductor element is protected against an external force. Further, it is possible to adopt the method of the present invention for manufacturing a semiconductor device to semiconductor elements of various thicknesses. Therefore, with the present invention, it is possible to provide, for example, a semiconductor device suitably adopted for use in various semiconductor modules such as mobile phones, disposable information terminal, thin-model display, laptop computers, and so on, and to provide a method for manufacturing such a semiconductor device.

Further, As mentioned above, a semiconductor module of the present invention is provided with the semiconductor device of the present invention.

Further, As mentioned above, a liquid crystal module of the present invention includes (I) a semiconductor device having an external connection terminal being connected with a liquid crystal panel, and (II) another external connection terminal connected with a printed wiring board. The liquid crystal module may be so arranged that, for example, the semiconductor device is connected with a connection-subjected element (the liquid crystal panel and the printed wiring board in the foregoing liquid crystal module), with the film substrate being bent in an U-shape. The semiconductor device of the present invention is suitable for a semiconductor module having the foregoing configuration. For example, the semiconductor device of the present invention is particularly suitable for a liquid crystal module having the foregoing configuration.

Thus, in the foregoing configuration, the semiconductor module (e.g. the liquid crystal module) has the semiconductor device of the present invention. Therefore, it is possible to provide a liquid crystal module and a semiconductor module, each of which (A) being capable of protecting the semiconductor element from an external force, (B) having a semiconductor device whose size is reduced, the semiconductor device having a higher strength and a higher packaging reliability than those of a conventional semiconductor device, and (C) being capable of ensuring a sufficient bendable region, even when the film substrate is bent at the time of installation. Further, in the present invention, since the semiconductor module (e.g. the liquid crystal module) has the semiconductor device of the present invention, the heat generated in a semiconductor element is efficiently dispersed. This restrains a change in a property of the semiconductor element. As a result, with the foregoing configuration, it is possible to provide a liquid crystal module and a semiconductor module, each of which being capable of (I) efficiently dispersing the heat generated in the semiconductor element, and (II) restraining a change in the property of the respective semiconductor element.

The present invention is not limited to the embodiments above, but may be altered within the scope of the claims. An embodiment based on a proper combination of technical means disclosed in different embodiments is encompassed in the technical scope of the present invention.

Further, the invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

1. A semiconductor device, comprising:
a film substrate on which a wiring pattern is provided; and
a semiconductor element having, on its active surface, a connection terminal to be connected with the wiring pattern, the semiconductor element being mounted on the film substrate so that the connection terminal and the wiring pattern face each other, wherein:
the semiconductor element is provided with sealing resin, and
the sealing resin has a two-layer structure including (a) a first sealing resin layer for sealing a connection region of the semiconductor element and the wiring pattern and (b) a second sealing resin layer being so provided to the semiconductor element that at least an exposed edge portion of the semiconductor element is sealed.

2. The semiconductor device as set forth in claim 1, wherein resin constituting the first sealing resin layer and resin constituting the second sealing resin layer are different from each other.

3. The semiconductor device as set forth in claim 2, wherein the second sealing resin layer is made of resin having a higher heat conductivity than that of the semiconductor element.

4. The semiconductor device as set forth in claim 3, wherein the second sealing resin layer completely covers a surface opposite to the active surface of the semiconductor element.

5. The semiconductor device as set forth in claim 1, wherein the first sealing resin layer and the second sealing resin layer are identical with each other in terms of a material thereof.

6. The semiconductor device as set forth in claim 1, wherein the second sealing resin layer covers only an edge portion of the semiconductor element, not being covered by the first sealing resin layer.

7. The semiconductor device as set forth in claim 1, further comprising a heat dispersing plate, laminated on a surface opposite to the active surface of the semiconductor element, which is made of a material whose heat conductivity is higher than that of the semiconductor element.

8. The semiconductor device as set forth in claim 7, wherein the second sealing resin layer is formed so as to cover the semiconductor element as well as the heat dispersing plate.

9. A method for manufacturing a semiconductor device having (a) a film substrate on which a wiring pattern is provided and (b) a semiconductor element having, on its active surface, a connection terminal to be connected with the wiring pattern, the semiconductor element being mounted on the film substrate so that the connection terminal and the wiring pattern face each other, the semiconductor element being provided with sealing resin,
the method comprising the step of providing the semiconductor element with the sealing resin, the step being carried out in two processes including:
a first sealing resin formation process in which (i) a connecting region of the semiconductor element and the wiring pattern is sealed with a first sealing resin and (ii) the first sealing resin is cured so as to form a second sealing resin layer; and
a second sealing resin layer formation process for (i) providing, to the semiconductor element, a second sealing resin, so that at least an exposed edge portion of the semiconductor element is sealed and (ii) curing the second sealing resin so that a second sealing resin layer is formed, the second sealing resin layer formation process being carried out after the first sealing resin layer formation process is carried out.

10. The method as set forth in claim 9, wherein resin constituting the first sealing resin and resin constituting the second sealing resin are different from each other.

11. The method as set forth in claim 9, wherein a heat dispersing plate laminating process is carried out between the first sealing resin layer formation process and the second sealing resin layer formation process, the heat dispersing plate laminating process being such that a heat dispersing plate made of a material having a higher heat conductivity than that of the semiconductor element is laminated on a surface opposite to the active surface of the semiconductor element.

12. The method as set forth in claim 9, wherein:
before the first resin sealing layer formation process and the second resin sealing layer formation process, there is carried out a heat dispersing plate laminating process in which a heat dispersing plate made of a material having a higher heat conductivity than that of the semiconductor element is laminated on a surface opposite to the active surface of the semiconductor element, and
there is carried out a semiconductor element mounting process for mounting, on the film substrate, the semiconductor element on which the heat dispersing plate is laminated.

13. A semiconductor module, comprising:
a semiconductor device having:
a film substrate on which a wiring pattern is provided;
a semiconductor element having, on its active surface, a connection terminal to be connected with the wiring pattern, the semiconductor element being mounted on the film substrate so that the connection terminal and the wiring pattern face each other, wherein:
the semiconductor element is provided with sealing resin, and
the sealing resin has a two-layer structure including (a) a first resin sealing layer for sealing a connection region of the semiconductor element and the wiring pattern and (b) a second resin sealing layer being provided to the semiconductor element, so that at least an exposed edge portion of the semiconductor element is sealed.

14. A liquid crystal module, comprising:
a semiconductor device having:
an external connection terminal being connected with a liquid crystal panel;
another external connection terminal connected with a printed wiring board;
a film substrate on which a wiring pattern is provided; and
a semiconductor element having, on its active surface, a connection terminal to be connected with the wiring pattern, the semiconductor element being mounted on the film substrate so that the connection terminal and the wiring pattern face each other, wherein:
the semiconductor element is provided with sealing resin, and
the sealing resin has a two-layer structure including (a) a first resin sealing layer for sealing a connection region of the semiconductor element and the wiring pattern and (b) a second resin sealing layer being so provided to the semiconductor element that at least an exposed edge portion of the semiconductor element is sealed.
